(19) United States
(12) Patent Application Publication
(10) Pub. No.: US 2018/0003503 A1
(43) Pub. Date: Jan. 4, 2018

(54) Damping of a Sensor

(71) Applicant: Infineon Technologies AG, Neubiberg (DE)

(72) Inventor: Marco Haubold, Dresden (DE)

(21) Appl. No.: 15/638,007

(22) Filed: Jun. 29, 2017

(30) Foreign Application Priority Data
Jun. 30, 2016 (DE) 102016112041.3

(51) Int. Cl. G01C 19/5726; G01P 15/125; G01P 1/00; B81B 7/02; H05K 5/03; B81B 3/00; G01P 15/08

(52) U.S. Cl. CPC G01C 19/5726; H05K 5/03; G01P 15/125; B81B 3/0018; G01P 1/003; B81B 7/02; G01P 2015/0882

(57) ABSTRACT

A device comprises a substrate, a spring structure, and a first sensor. The first sensor is resiliently coupled with the substrate via the spring structure. The spring structure is configured to provide damping of the first sensor with respect to the substrate. The device also comprises a second sensor configured to sense a deflection of the spring structure.

### CROSS-REFERENCE TO RELATED APPLICATIONS

This application claims the benefit of German Patent Application No. 10 2016 112 041.3, entitled “Damping of a Sensor,” filed on Jun. 20, 2016, which application is incorporated herein by reference.

### TECHNICAL FIELD

Various examples relate to a device comprising a substrate, a spring structure, and a first sensor. The first sensor is resiliently coupled with the substrate via the spring structure. The spring structure is configured to provide damping of the first sensor with respect to the substrate.

The device further comprises a second sensor configured to sense a deflection of the spring structure.

### BACKGROUND

Due to their capability of compact integration and the availability of flexible design choices, microelectromechanical systems (MEMS) are desirable for sensing, e.g., ambient pressure. Potential applications are vast: navigation or positioning applications may benefit from correlating a change of the ambient pressure with an otherwise detected change in elevation of the respective device.

However, it is known that changes in the sensor signal of the MEMS pressure sensor can be caused by further external influences other than changes in the ambient pressure itself. Such external influences are referred to as interference. Interferences tend to degrade the accuracy of the measurement.

One source of interference is mechanical stress of the substrate on which the sensor is integrated. There are different sources for mechanical stress: typically, the design and implementation of a device comprising a MEMS pressure sensor requires the use of a plurality of different materials. Often, such different materials have different physical properties including different expansion coefficients and elasticities. Then, a change in the ambient temperature induces mechanical stress. Such thermomechanical stress may lead to significant interference, thereby increasing the measurement error.

Thus, a need exists to reduce or compensate for such interferences. This is typically achieved by damping. Damping decouples—e.g., mechanically decoupled—the MEMS pressure sensor to some degree from the substrate and the surrounding. Damping enables the absorption of mechanical stress. Damping can be achieved by attaching the housing of the MEMS pressure sensor to the substrate using an adhesive polymer. The polymer absorbs the mechanical stress and thereby decouples the MEMS pressure sensor from the substrate. Thereby, external stress is absorbed by the polymer. Thereby, increased durability and mechanical stability can be provided in addition to reduction of interference from thermomechanical stress.

However, such damping may not reduce all sources of interference. A further source of interference are changes in the orientation of the MEMS pressure sensor. Changes in the orientation can cause a change of the corresponding sensor signal even if the ambient pressure remains constant. Thus, in order to correct for such interferences, it is desirable to sense the orientation and/or acceleration of the MEMS pressure sensor.

In one example according to reference implementations, the MEMS pressure sensor and a separate second sensor are arranged on a common substrate. The second sensor allows to sense acceleration. However, such an approach faces certain restrictions and drawbacks. By separately integrating the MEMS pressure sensor and the second sensor, increased requirements of space result.

An alternative approach comprises monolithic integration of, both, the MEMS pressure sensor, as well as the second sensor on the substrate of the device. Here, the MEMS pressure sensor is coupled via a dampening structure with the substrate. However, also such an approach faces certain drawbacks and restrictions. The MEMS pressure sensor and the second sensor are integrated separately which still results in an increased requirement of space on the substrate.

### SUMMARY

Therefore, a need exists for advanced techniques of integrating sensors on a substrate. In particular, need exists for techniques which overcome or mitigate at least some of the above-identified drawbacks and restrictions.

This need is met by the features of independent claim 1. The dependent claims define embodiments.

According to an example, device comprises a substrate, a spring structure, and a first sensor. The first sensor is resiliently coupled with the substrate via a spring structure. The spring structure is configured to provide damping of the first sensor with respect to the substrate. The device further comprises the second sensor configured to sense a deflection of the spring structure.

According to an example, a method is provided. The method comprises a first sensor sensing a physical observable. The method further comprises a spring structure providing damping to the first sensor. The method further comprises a second sensor sensing the deflection of the spring structure.

The examples described above and the examples described hereinafter may be combined with each other and further examples.

### BRIEF DESCRIPTION OF THE DRAWINGS

FIG. 1 schematically illustrates a device comprising a substrate, a spring structure, a first sensor, and a second sensor according to various embodiments.

FIG. 2 illustrates a degree of freedom of translational motion of the first sensor of the device of FIG. 1 according to various embodiments.

FIG. 3 illustrates a degree of freedom of rotational motion of the first sensor of the device of FIG. 1 according to various embodiments.

FIG. 4 illustrates schematically distance-variable capacitive sensing of the second sensor of the device according to FIG. 1.

FIG. 5 illustrates schematically area-variable capacitive sensing of the second sensor of the device according to FIG. 1.

FIG. 6 schematically illustrates the device comprising a first sensor and the second sensor according to FIG. 1, the device further comprising circuitry for receiving sensor signals from the first sensor and the second sensor, respectively, according to various embodiments.

FIG. 7 is a flowchart of a method according to various embodiments.

### DETAILED DESCRIPTION OF ILLUSTRATIVE EMBODIMENTS

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Hereinafter, various aspects with respect to a device comprising a first sensor and a second sensor are disclosed. The first sensor and/or the second sensor may be MEMS-based. The first sensor and the second sensor may be monolithically integrated on a substrate of the device.

The first sensor may output a sensor signal which is indicative of a physical observable. An example of a physical observable that may be sensed by the first sensor is ambient pressure. However, the techniques described herein are not limited to pressure sensors. E.g., in other examples, the sensor signal of the first sensor may be indicative of ambient temperature, humidity, etc.

Some aspects relate to providing damping of the first sensor with respect to the substrate. The damping may be achieved by a spring structure. The spring structure may be MEMS-based; as such the spring structure may comprise one or more micromechanical elements. By means of the damping provided by the spring structure, stress decoupling of the first sensor with respect to the substrate may be achieved. Thereby, more accurate sensing of the respective physical observable by means of the first sensor can be achieved, because interference is reduced.

According to examples, a second sensor is provided which is configured to sense a deflection of the spring structure. The techniques are based on the finding that the deflection of the spring structure is typically indicative of the acceleration or external force acting on the device and, in particular, the first sensor. By sensing the deflection of the spring structure, the need of providing a separate acceleration sensor is reduced. Instead, by sensing the deflection of the spring structure, a value may be obtained based on a sensor signal of the second sensor which is indicative of the external force acting on the device in a particular simple manner.

Thus, the spring structure—used for damping of the first sensor—can be reused for detecting the position of the first sensor with respect to the substrate. In addition to stress decoupling, it is possible to sense external forces acting on the first sensor; this may include an orientation of the first sensor with respect to gravity or other forces present, e.g., due to shock or acceleration of the device.

The techniques allow reducing the required substrate area for integration of the device. The efficient use of the available area on the substrate reduces costs as well as complexity and manufacturing. Due to the integrated damping and force-sensing, highly precise measurements are possible. In particular, the sensor signal of the second sensor can be used in order to compensate for cross-sensitivities of the first sensor with respect to acceleration and/or orientation of the device.

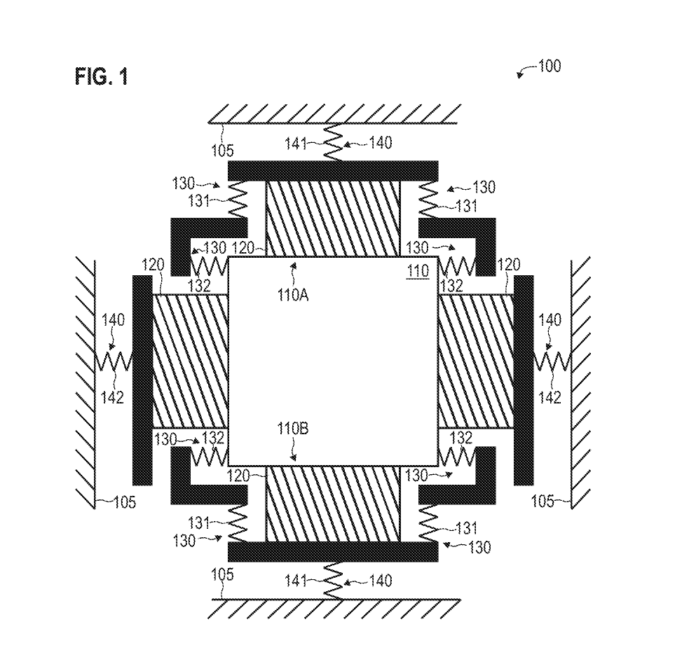

FIG. 1 schematically illustrates a device according to an example. The device 100 comprises a substrate 105, e.g., Silicon or another semiconductor. The device 100 further comprises the first sensor 110 and the second sensor 120. The first sensor 110 and the second sensor 120 are illustrated schematically in FIG. 1: both can comprise certain structures, e.g., MEMS-based structures (not shown in FIG. 1).

The first sensor 110 may be configured to output a first sensor signal indicative of at least one of the following: an ambient pressure; and an ambient temperature.

The first sensor 110 and the second sensor 120 may be arranged in a recess formed in the substrate 105. E.g., the recess may be formed by etching.

The first sensor 110, as well as the second sensor 120 and the remaining elements of the device 100 can be monolithically integrated on the substrate 105. The first sensor 110 and/or the second sensor 120 can be MEMS-based.

The device 100 further comprises a spring structure 130. The spring structure 130 is coupled between the substrate 105 and the first sensor 110. Thereby, the first sensor 110 can move with respect to the substrate 105. The spring structure 130 is configured to provide damping of the first sensor 110 with respect to the substrate. The damping mechanically decouples the first sensor 110 to a certain degree from the substrate 105.

The functioning of the damping of the spring structure 130 will be explained next. The system comprising the substrate 105, the spring structure 130, and the first sensor 110 can be treated as damped harmonic oscillator having the equation of motion:

m\ddot{x}+d\dot{x}+kx=F, (1)

where x denotes the position of the first sensor 110 with respect to the substrate 105, m denotes the mass of the first sensor 110, k is the spring force of the spring structure 130, d is the friction coefficient, and F is the external force applied. See Kaajakari, Ville. “Practical MEMS: Design of microsystems, accelerometers, gyroscopes, RF MEMS, optical MEMS, and microfluidic systems.” Las Vegas, Nev.: Small Gear Publishing (2009) for details.

External forces may be, e.g., the gravitational force or force due to an acceleration pulse. The external forces thus leads to a displacement of the motion-damped first sensor 110. The amplitude x of the displacement depends on the quality Q and eigenfrequency ωₒ of the oscillator according to the following equation:

$$x = \frac{F / m}{{s}^{2} + s \times {ω}_{0} / Q + {ω}_{0}^{2}} . \qquad ( 2 )$$

s denotes Laplace's operator.

Thus, from Eq. 2 it follows that by detecting the deflection of the spring structure 130, it is possible to determine the force or acceleration acting on the first sensor 110.

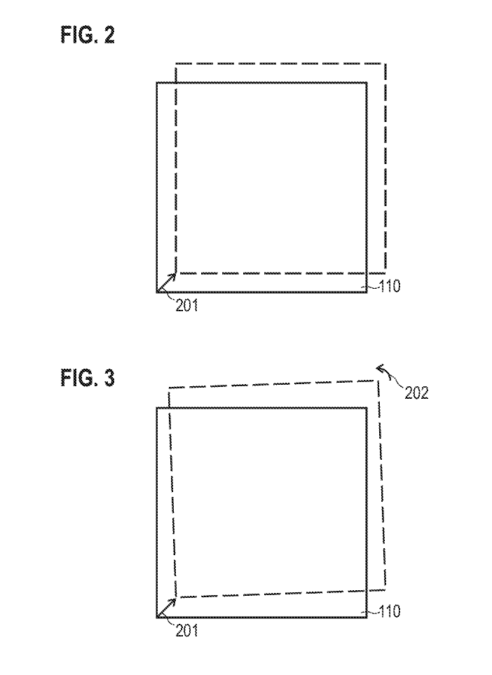

The spring structure 130 is configured to provide at least two degrees of freedom of motion to the first sensor 110. Referring to FIG. 2, the spring structure 130 enables translational displacement 201 in the plane of the substrate 105 (drawing planes of FIGS. 1 and 2). The spring structure 130 can also enable translational displacement perpendicular to the plane of the substrate 105 (not shown in FIG. 2). Further referring to FIG. 3, the spring structure 130 enables rotational displacement 202 in the plane of the substrate 105.

By implementing the spring structure 130 to provide the at least two degrees of freedom of motion 201, 202, efficient damping is possible: thereby, stress of the substrate 105 can be efficiently absorbed by the spring structure 130.

Referring again to FIG. 1: the spring structure 130 in the example of FIG. 1 comprises first micromechanical elements 131 providing a first-degree for freedom of translational motion 201 (up-down direction in FIG. 1) and further comprise a second micromechanical elements 132 providing a second degree of freedom of translational motion 201 to the first sensor 110 (left-right direction in FIG. 1).

E.g., the micromechanical elements 131, 132 may be zigzag-shaped free-standing bridges. Other implementations are conceivable. By virtue of their shape and/or material, the micromechanical elements 131, 132 may be deformed. This provides resilience to the system.

As can be seen, the micromechanical elements 131, 132 are arranged perpendicularly with respect to each other. Further, the first micromechanical elements 131 and the second micromechanical elements 132 are coupled in series between the first sensor 110 and the substrate 105. Such a series connection is sometimes referred to as cascaded micro-oscillator. A cascaded micro-oscillator provides a large maximum deflection/path of travel to the first sensor 110.

In alternative implementations, it would also be possible that the first micromechanical elements 131 and the second micromechanical elements 132 are coupled in parallel in between the first sensor 110 and the substrate 105.

In the example of FIG. 1, the first micromechanical elements 131 are provided on two opposing sides 110A, 110B of the first sensor 110 (in FIG. 1, the upper side and the lower side). Likewise, the second micromechanical elements 132 are provided on the same two opposing sides 110A, 110B of the first sensor 110 (In FIG. 1, the upper side and the lower side). This enables efficient damping of the first sensor 110 with respect to the substrate 105. In further examples, further micromechanical elements could be provided on further sides of the first sensor 110 (not shown in FIG. 1).

The device 100 further comprises a further spring structure 140. The further spring structure 140 comprises micromechanical elements 141, 142 which are arranged on opposing sides of the first sensor 110 and the second sensor 120. The micromechanical elements 141, 142 of the further spring structure 140 may be implemented corresponding to the implementation of the micromechanical elements 131, 132 of the spring structure 130.

The further spring structure 140 is coupled between the second sensor 120 and the substrate 105, as well as between the spring structure 130 and the substrate 105. Thereby, the further spring structure 140 provides damping of the second sensor 110 and the spring structure 130 with respect to the substrate 105. Stress acting on the substrate 105 is thereby absorbed by the further spring structure 140 and prevented from interfering with the measurements taken by the second sensor 120, as well as by the first sensor 110. With respect to the first sensor 110, the further spring structure 140 adds another layer of damping.

In some examples, the spring force of the spring structure 130 may be dimensioned to be larger than the spring force of the further spring structure 140. E.g., the spring force of the spring structure 130 can be dimensioned to be 2-20 times larger than the spring force of the further spring structure 140, preferably 5-10 times larger.

The spring force of the further spring structure can be dimensioned to absorb stress acting on the substrate 105. The spring force of the spring structure 130 can be dimensioned to enable sufficient displacement of the sensor 110 given the comparably heavy-weight structure of the first sensor 110. The spring force of the spring structure 130 can be dimensioned to sufficiently damp oscillation of the first sensor 110. Thereby, an equilibrium state according to Eq. 2 can be reached on a short timescale.

The device 100 may further comprise electrical traces between the first sensor 110 and circuitry which is configured to receive a first sensor signal from the first sensor 110 (the electrical traces and the circuitry are not shown in FIG. 1). The electrical traces are configured to forward the first sensor signal. In particular, it is possible that the electrical traces are at least partially arranged on the spring structure 130. E.g., the electrical traces can be arranged on the surface of the micromechanical elements 131, 132 implementing the spring structure 130. The electrical traces could also be embedded into a multi-layer structure of the micromechanical elements 131, 132. Likewise, it is possible that the electrical traces are at least partially arranged on the further spring structure 140 in a corresponding manner.

The circuitry may determine an output signal based on the first sensor signal. E.g., the output signal may be indicative of the ambient pressure or the ambient temperature, etc.

Such circuitry can, alternatively or additionally, be configured to receive a second sensor signal from the second sensor 120. Based on the second sensor signal, the circuitry may output an output signal which is indicative of at least one of the following: an acceleration of the device 100; and an inclination of the device 100, e.g., with respect to gravity.

In some examples, the circuitry may provide only a single output signal which is indicative of the physical observable sensed by the first sensor. The circuitry may be configured to determine the output signal based on, both, the first sensor signal, as well as the second sensor signal. Thereby, measurement errors may be reduced.

It is possible that the first sensor 110 and/or the second sensor 120 operate according to at least one of the following measurement principles: capacitive sensing; piezoresistive sensing; conductivity sensing; area-variable capacitive sensing; and distance-variable capacitive sensing.

E.g., for piezoresistive sensing, a length change and/or a shape change—such as a bending—of probing traces may translate into a change of resistivity of the probing traces. Conductivity sensing may comprise a mechanical switch which is selectively closed depending on the position of a moveable part of the first sensor.

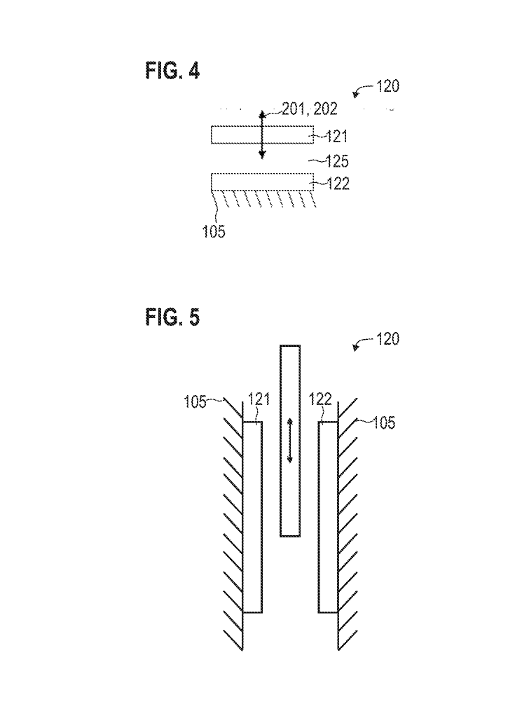

FIG. 4 illustrates aspects with respect to distance-variable capacitive sensing. Here, a first electrode 121 of the second sensor 120 and a second electrode 122 of the second sensor 120 are arranged offset from each other, separated by a gap 125. E.g., the electrode 121 may be coupled with the first sensor 110; while the electrode 122 may be coupled with the substrate 105 or the further spring structure 140. In response to translational motion 201 and/or rotational motion 202 of the first sensor 110, the distance between the electrodes 121, 122 changes. Thereby, the capacitance of the electrode system formed by the electrodes 121, 122 changes. This change of capacitance can be detected. This enables to sense the deflection of the spring structure 130 and/or the position of the first sensor 110 with respect to the substrate 105.

FIG. 5 illustrates aspects with respect to area-variable capacitive sensing. Here, both electrodes 121, 122 of the second sensor 120 are fixedly attached to the substrate 105. The dielectric constant of the matter in the gap 125 changes depending on the translational motion 201 and/or rotational motion 202. Thereby, the capacitance of the electrode system formed by the electrodes 121, 122 changes. The change of capacitance can be detected. This enables to sense the deflection of the spring structure 130 and/or the position of the first sensor 110 with respect to the substrate 105.

Thus, for the second sensor 120, the detection of the position of the first sensor 110 can be achieved by applying an electrical field between the two electrodes 121, 122. The electrodes 121, 122 can be electrically isolated with respect to the surrounding. The substrate 105 may further act as electrical shielding and may thus facilitate accurate capacitive sensing.

If the electrodes 121, 122 are structured perpendicular to the surface of the substrate 105, it is possible to reduce the required space for implementation of the second sensor 120.

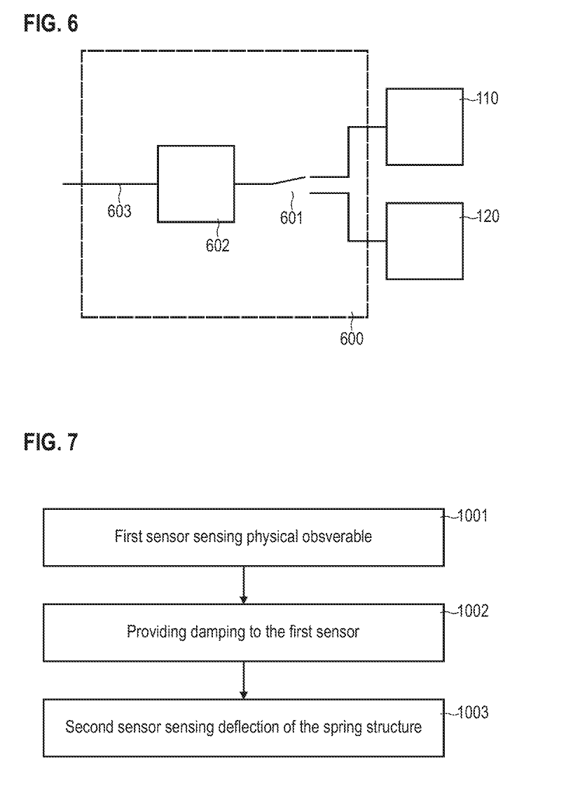

FIG. 6 schematically illustrates aspects with respect to circuitry 600 for evaluating the first sensor signal received from the first sensor 110 and the second sensor signal 120 received from the second sensor 120. The circuitry 600 comprises a switch 601 which selectively couples a processing element 602 with the first sensor 110 or the second sensor 120. E.g., the switch 601 may be a solid-state switch such as a diode or a field-effect transistor.

Depending on the position of the switch, either the first sensor signal is received by the processing element 602 or the second sensor signal is received by the processing element 602. The processing element 602 analyzes the first sensor signal and/or the second sensor signal and outputs an output signal via the respective output interface 603.

E.g., the processing element can comprise elements selected from the group comprising: a reference capacitance; a reference resistance; a current source; a voltage source; etc.

E.g., the circuitry 600 can be implemented as an integrated circuit and/or an application-specific integrated circuit (ASIC).

In some examples, it is possible to implement the first sensor and the second sensor according to the same measurement principle, e.g., capacitive sensing or resistive sensing, etc. Then, it is possible to re-use the same circuitry, and in particular re-use the same processing element 602 for analyzing the first sensor signal received from the first sensor and the second sensor signal received from the second sensor. Here, a time-division duplexing (TDD) technique can be employed to alternatingly analyze the first and second sensor signals. Re-using at least parts of the circuitry 600 enables to reduce the required space for integration, reduces costs, and complexity.

FIG. 7 is a flowchart of a method according to examples. At 1001, the first sensor 110 senses a physical observable, e.g., temperature.

At 1002, the spring structure 130 provides damping to the first sensor 110. As such, the spring structure 130 mechanically decouples the first sensor 110 to some extent from the substrate 105.

At 1003, the second sensor 120 senses deflection of the spring structure 130. For this, capacitive sensing and/or piezoresistive sensing may be employed. The deflection of the spring structure 130 typically correlates with the position of the first sensor 110. The deflection of the spring structure 130 can be indicative of an external force acting on the device 100 or an acceleration of the device 100.

Summarizing, above techniques of implementing a first sensor and a second sensor for acceleration sensing in a highly integrated manner have been disclosed. The first sensor may sense ambient pressure or temperature, etc.

The first sensor and the second sensor may be monolithically integrated on the same substrate. Further, circuitry for analyzing sensor signals received from the first sensor and the second sensor may be monolithically integrated with the sensors on the same substrate and, thus, the same die or chip.

Such a highly integrated approach allows correction of the first sensor signal received from the first sensor based on the sensed acceleration of the second sensor. Thereby, external influences such as thermomechanical stress or any other external force on the measurement accuracy of the further sensor may be reduced.

Thus, above at least the following examples have been described in detail:

### Example 1

A device, comprising: a substrate, a spring structure, a first sensor resiliently coupled with the substrate via the spring structure, the spring structure being configured to provide damping of the first sensor with respect to the substrate, and a second sensor configured to sense a deflection of the spring structure.

### Example 2

The device of example 1, wherein the spring structure is configured to provide at least two degrees of freedom of motion to the first sensor.

### Example 3

The device of example 2, wherein the spring structure comprises at least one first micromechanical element providing a first degree of freedom of translational motion to the first sensor and further comprises at least one second micromechanical element providing a second degree of freedom of translational motion to the first sensor, the second degree of freedom being different from the first degree of freedom.

### Example 4

The device of example 3, wherein the at least one first micromechanical element and the at least one second micromechanical element are coupled in series between the first sensor and the substrate.

### Example 5

The device of examples 3, wherein a first one of the at least one first micromechanical element is arranged on a first side of the first sensor, wherein a second one of the at least one first micromechanical element is arranged on a second side of the first sensor, the second side being opposite to the first side, wherein a first one of the at least one second micromechanical element is arranged on the first side of the first sensor, wherein a second one of the at least one second micromechanical element is arranged on the second side of the first sensor.

### Example 6

The device of example 1, further comprising: a further spring structure coupled between the second sensor and the substrate, wherein the second sensor is resiliently coupled with the substrate via the at least one further spring structure, the further spring structure being configured to provide damping of the second sensor with respect to the substrate.

### Example 7

The device of example 1, further comprising: a further spring structure coupled between the spring structure and the substrate, wherein the spring structure is resiliently coupled with the substrate via the further spring structure, the further spring structure being configured to provide damping of the spring structure with respect to the substrate.

### Example 8

The device of example 6, wherein the spring force of the spring structure is 2-20 times larger than the spring force of the further spring structure, preferably 5-10 times.

### Example 9

The device of example 6, wherein the spring force of the further spring structure is dimensioned to absorb thermomechanical stress acting on the substrate.

### Example 10

The device of example 1, further comprising: electrical traces between the first sensor and circuitry configured to receive a first sensor signal from the first sensor, the electrical traces being configured to forward the first sensor signal, wherein the electrical traces are at least partially arranged on the spring structure.

### Example 11

The device of example 1, further comprising: circuitry configured to receive a second sensor signal from the second sensor and to determine, based on the second sensor signal, an output signal indicative of at least one of the following: an acceleration of the device; and an inclination of the device.

### Example 12

The device of example 1, further comprising: circuitry configured to selectively receive a first sensor signal from the first sensor or a second sensor signal from the second sensor depending on an operational mode of a switch.

### Example 13

The device of example 1, wherein the first sensor and/or the second sensor operates according to at least one of the following measurement principles: capacitive sensing; piezoresistive sensing; conductivity sensing; area-variable capacitive sensing; and distance-variable capacitive sensing.

### Example 14

The device of example 1, wherein the second sensor comprises at least one first electrode and at least one second electrode, the first electrode being coupled to the first sensor.

### Example 15

The device of example 7, wherein the second electrode is coupled to the further spring structure.

### Example 16

The device of example 1, wherein the second sensor is configured to output a second sensor signal indicative of the relative position of the first sensor with respect to the substrate.

### Example 17

The device of example 1, wherein the first sensor is configured to output a first sensor signal indicative of at least one of the following: an ambient pressure; and an ambient temperature.

### Example 18

The device of example 1, wherein the first sensor and the second sensor are monolithically integrated on the substrate.

### Example 19

The device of example 1, wherein the first sensor is microelectromechanically integrated.

### Example 20

A method, comprising: a first sensor sensing a physical observable, a spring structure providing damping to the first sensor, and a second sensor sensing a deflection of the spring structure.

Although the invention has been shown and described with respect to certain preferred embodiments, equivalents and modifications will occur to others skilled in the art upon the reading and understanding of the specification. The present invention includes all such equivalents and modifications and is limited only by the scope of the appended claims.

What is claimed is:

1. A device comprising:
a substrate;
a spring structure;
a first sensor resiliently coupled with the substrate via the spring structure, the spring structure being configured to provide damping of the first sensor with respect to the substrate; and
a second sensor configured to sense a deflection of the spring structure.

2. The device of claim 1, further comprising:
a further spring structure coupled between the second sensor and the substrate,
wherein the second sensor is resiliently coupled with the substrate via the at least one further spring structure, the further spring structure being configured to provide damping of the second sensor with respect to the substrate.

3. The device of claim 2,
wherein the spring force of the spring structure is 2-20 times larger than the spring force of the further spring structure.

4. The device of claim 1, further comprising:
a further spring structure coupled between the spring structure and the substrate,
wherein the spring structure is resiliently coupled with the substrate via the further spring structure, the further spring structure being configured to provide damping of the spring structure with respect to the substrate.

5. The device of claim 4,
wherein the spring force of the spring structure is 2-20 times larger than the spring force of the further spring structure.

6. The device of claim 5,
wherein the spring force of the further spring structure is dimensioned to absorb thermomechanical stress acting on the substrate.

7. The device of claim 6, wherein the second sensor comprises at least one first electrode and at least one second electrode, the first electrode being coupled to the first sensor, and wherein the second electrode is coupled to the further spring structure.

8. The device of claim 1, further comprising:
electrical traces between the first sensor and circuitry configured to receive a first sensor signal from the first sensor, the electrical traces being configured to forward the first sensor signal, wherein the electrical traces are at least partially arranged on the spring structure.

9. The device of claim 1, further comprising:
circuitry configured to receive a second sensor signal from the second sensor and to determine, based on the second sensor signal, an output signal indicative of at least one of the following: an acceleration of the device; and an inclination of the device.

10. The device of claim 1, further comprising:
circuitry configured to selectively receive a first sensor signal from the first sensor or a second sensor signal from the second sensor depending on an operational mode of a switch.

11. The device of claim 1,
wherein the first sensor or the second sensor uses capacitive sensing, piezoresistive sensing, conductivity sensing, area-variable capacitive sensing, or distance-variable capacitive sensing.

12. The device of claim 1,
wherein the second sensor comprises a first electrode and a second electrode, the first electrode being coupled to the first sensor.

13. The device of claim 1,
wherein the second sensor is configured to output a second sensor signal indicative of the relative position of the first sensor with respect to the substrate.

14. The device of claim 1,
wherein the first sensor is configured to output a first sensor signal indicative of an ambient pressure or an ambient temperature.

15. The device of claim 1,
wherein the first sensor and the second sensor are monolithically integrated on the substrate.

16. The device of claim 1,
wherein the first sensor is microelectromechanically integrated.

17. A device comprising:
a substrate;
a spring structure;
a first sensor resiliently coupled with the substrate via the spring structure, the spring structure being configured to provide damping of the first sensor with respect to the substrate; and
a second sensor configured to sense a deflection of the spring structure, wherein the spring structure is configured to provide two degrees of freedom of motion to the first sensor.

18. The device of claim 17, wherein the spring structure comprises a first micromechanical element providing a first degree of freedom of translational motion to the first sensor and a second micromechanical element providing a second degree of freedom of translational motion to the first sensor, the second degree of freedom being different from the first degree of freedom.

19. The device of claim 18,
wherein the first micromechanical element is arranged on a first side of the first sensor,
wherein a third micromechanical element providing the first degree of freedom of translational motion to the first sensor is arranged on a second side of the first sensor, the second side being opposite to the first side,
wherein the second micromechanical element is arranged on the first side of the first sensor,
wherein a fourth micromechanical element providing a second degree of freedom of translational motion to the first sensor is arranged on the second side of the first sensor.

20. The device of claim 18,
wherein the first micromechanical element and the second micromechanical element are coupled in series between the first sensor and the substrate.

21. The device of claim 20,
wherein the first micromechanical element is arranged on a first side of the first sensor,
wherein a third micromechanical element providing a first degree of freedom of translational motion to the first sensor is arranged on a second side of the first sensor, the second side being opposite to the first side,
wherein the second micromechanical element is arranged on the first side of the first sensor,
wherein a fourth micromechanical element providing a second degree of freedom of translational motion to the first sensor is arranged on the second side of the first sensor.

22. A method comprising:
sensing a physical observable at a first sensor;
providing damping to the first sensor using a spring structure; and
sensing a deflection of the spring structure at a second sensor.
